(19) United States
(12) Patent Application Publication
(10) Pub. No.: US 2010/0258174 A1
(43) Pub. Date: Oct. 14, 2010

(54) GLOBAL OPTIMIZATION OF THIN FILM PHOTOVOLTAIC CELL FRONT COATINGS

(76) Inventors: Michael Ghebrebrhan, Cambridge, MA (US); Peter Bermel, Cambridge, MA (US); Yehuda Avniel, Cambridge, MA (US); John D. Joannopoulos, Belmont, MA (US); Steven G. Johnson, Cambridge, MA (US)

Correspondence Address: Tauthier & Connors LLP;Suite 2300, 225 Franklin Street, Boston, MA, 02110, US

(21) Appl. No.: 12/423,405

(22) Filed: Apr. 14, 2009

(51) Int. Cl. H01L 31/0232; H01L 31/18

(52) U.S. Cl. 136/256; 438/72; 257/E31.127

(57) ABSTRACT

A solar cell includes a thin film photovoltaic material structure used in absorbing light of a selective bandwidth. A multitude of dielectric front coatings are positioned on the thin film photovoltaic material structure so as to maximize admittance over the selected bandwidth. The thicknesses and indices of each of the front coatings are chosen by a global-optimization procedure to maximize the short-circuit current of the solar cell.

### GOVERNMENTAL SPONSORSHIP INFORMATION

This invention was made with Government support under Grant No. DMR 0819762, awarded by the National Science Foundation and also under Grant No. DAAD-19-02-D002, awarded by the Army Research Office. The Government has certain rights in the invention.

### BACKGROUND OF THE INVENTION

The invention is related to the field of solar cells, and in particular to the global optimization of thin film photovoltaic cell front coatings.

Front coatings are a critical feature of the highest-efficiency photovoltaic cells, ranging from monocrystalline silicon cells with double-layer anti-reflection (AR) coatings to thin-film CIGS cells with single-layer AR coatings. The most effective front coatings allow light over a broad range of wavelengths to enter the cell and be absorbed. This broad range of wavelengths extends from long-wave ultraviolet (around 300 nm) to the band gap wavelength (for silicon, 1108 nm). While single-layer front coating designs are well known, multiple layers could conceivably allow higher admittance over a broader bandwidth. Thus, the problem of optimizing multilayer coatings for solar cells has been a topic of great interest for some time, but the full range of possible designs had not been explored, especially for thin absorbers and/or multiple coatings.

For the most common type of solar cell, made from silicon wafers, the front-coating design problem mostly reduces to a broad-band anti-reflection problem with dispersion. However, due to the dispersion of silicon and the non-uniformity of the AM1.5 solar spectrum, this problem can only be solved approximately with an analytical approach. More precise solutions require a numerical approach treat the cases of single-layer and double-layer AR coatings, and triple-layer AR coatings. Similar approaches have been taken for other related wide-band absorption problems. Some authors have even expanded this problem to include long wavelengths beyond the bandgap of silicon.

On the other hand, emerging thin-film solar cell technology presents an entirely different challenge for front coating design. First of all, reflections from the front and back interfere over a broad range of wavelengths. Furthermore, unlike a narrow bandwidth problem, where the principles of Q-matching resonant absorption (also known as “impedance-matching”) can be applied, the portion of the solar spectrum considered is broad-bandwidth: e.g., 300 nm to 1100 nm. Moreover the absorption length over the bandwidth is typically greater than the physical optical path length. As a consequence, even light that initially passes through the front coating often reflects back out through the front without being absorbed. Front coatings must not only allow light to enter the silicon cell, but must also trap it to be absorbed. This increases the complexity of the problem while diminishing the accuracy of any analytical approximations. This was examined through ray tracing on a non-systematic basis for thick multicrystalline wafer-based cells. Some recent work on the opposite limit of extremely thin (15 nm) organic cells has demonstrated 40% boosts in relative efficiency with appropriately designed front coatings. Other previous work used metal and dielectric regions in the back in order to maximize fields near the active region of amorphous silicon.

### SUMMARY OF THE INVENTION

According to one aspect of the invention, there is provided a solar cell. The solar cell includes a thin film photovoltaic material structure used in absorbing light of a selective bandwidth. A multitude of dielectric front coatings are positioned on the thin film photovoltaic material structure so as to maximize admittance over the selected bandwidth. The thicknesses and indices of each of the front coatings are chosen by a global-optimization procedure to maximize the short-circuit current of the solar cell.

According to another aspect of the invention, there is provided a method of forming a solar cell. The method includes providing a thin film photovoltaic material structure used in absorbing light of a selective bandwidth. Also, the method includes positioning a multitude of dielectric front coatings on the thin film photovoltaic material structure so as to maximize admittance over the selected bandwidth. The thicknesses and indices of each of the front coatings are chosen by a global-optimization procedure to maximize the short-circuit current of the solar cell.

### BRIEF DESCRIPTION OF THE DRAWINGS

FIGS. 1A-1C are schematic diagrams of the various solar cell designs used in accordance with the invention;

FIGS. 2A-2C are graphs illustrating the real indices and absorption lengths of silicon, and current weights w(λ) used in J_{SC} calculation;

FIG. 3 is a graph illustrating a contour plot of the FOM of a cell with two front-coating layers versus the layer thickness;

FIG. 4 is a graph illustrating generated current efficiency of different front coating structures, each optimized at a specific wavelength;

FIG. 5 is a graph illustrating generated current efficiency versus the bandwidth of incoming radiation;

FIG. 6 is a graph illustrating absorption spectrum over the full absorbing bandwidth for a thin-film crystalline silicon solar cell optimized over the full bandwidth and optimized only at λ=902.8 nm;

FIG. 7 is a table illustrating values of the front coating indices, thicknesses and figure of merit for the optimized structures of FIG. 6;

FIG. 8 is a graph illustrating the figure of merit as a function of silicon slab thickness;

FIG. 9 is a graph illustrating relative difference in figure of merit, calculated as the relative difference of the FOM for the optimized structure with the given reflection phase and the FOM of a structure with the given phase and with the optimized front coating of the reference phase (θ=0), versus the Fresnel reflection amplitude phase of the silicon-metal boundary; and

FIG. 10 is a graph illustrating absorption spectrum of the optimized single front coating reference structure for two different back-reflector phases;

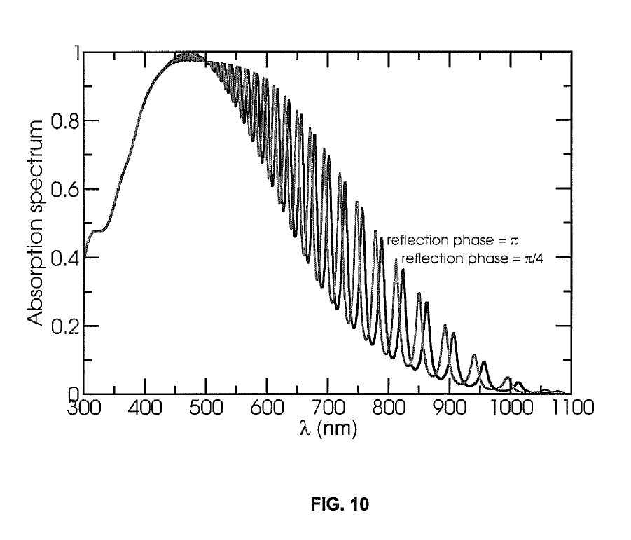

### DETAILED DESCRIPTION OF THE INVENTION

The invention provides a front-coating (FC) of a solar cell that controls its efficiency, determining admission of light into the absorbing material and potentially trapping light to enhance thin absorbers. Single-layer FC designs are well known, especially for thick absorbers where their only purpose is to reduce reflections. Multilayer FCs could improve performance, but require global optimization to design. For narrow bandwidths, one can always achieve nearly 100% absorption. For the entire solar bandwidth, however, a second FC layer improves performance by 6.1% for 256 μm wafer-based cells, or by 3.6% for 2 μm thin-film cells, while additional layers yield rapidly diminishing returns.

Emerging thin-film solar cell technology presents an entirely different challenge for front coating design. First of all, reflections from the front and back interfere over a broad range of wavelengths. Furthermore, unlike a narrow bandwidth problem, where the principles of Q-matching resonant absorption (also known as “impedance-matching”) can be applied, the portion of the solar spectrum considered is broad-bandwidth: e.g., 300 nm to 1100 nm. Moreover the absorption length over the bandwidth is typically greater than the physical optical path length. As a consequence, even light that initially passes through the front coating often reflects back out through the front without being absorbed. And front coatings must not only allow light to enter the silicon cell, but must also trap it to be absorbed. This increases the complexity of the problem while diminishing the accuracy of any analytical approximations. This was examined through ray tracing on a non-systematic basis for thick multicrystalline wafer-based cells. Some recent work on the opposite limit of extremely thin (15 nm) organic cells has demonstrated 40% boosts in relative efficiency with appropriately designed front coatings.

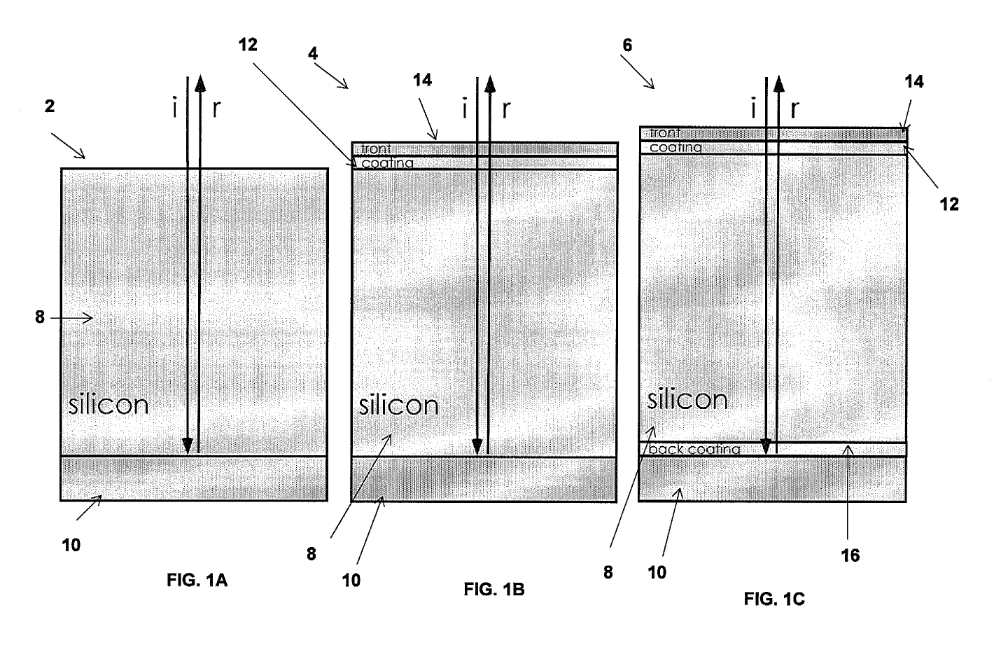

It is important to consider the behavior of the cell designs depicted in FIGS. 1A-1C. In particular, FIG. 1A shows a cell structure 2 having photovoltaically active silicon region 8, backed by a perfectly reflecting metal 10. FIG. 1B shows a cell structure 4 similar to FIG. 1A with the addition of front coatings 12, 14, and FIG. 1C shows a cell structure 6 similar to FIG. 1B with one back dielectric coating layer 16.

FIGS. 1B-1C show photovoltaically active silicon regions 8 backed by perfectly reflecting metal regions 10 with a varying number of dielectric coatings 12, 14 added to the front end and back 16. As long as the back coating 16 includes low-loss planar layers, its specific design will have negligible impact on the wide-bandwidth problem, though it will have a large impact on the narrow-bandwidth problem. The thicknesses and indices of each front coating 12, 14 are chosen by an exhaustive global-optimization procedure to maximize the short-circuit current of each cell. Also, various other photovoltaic (PV) materials beside silicon can be used such as cadmium telluride (CdTe), copper gallium indium selenide (CIGS), amorphous silicon (a-Si), and hydrogenated amorphous silicon (a-Si:H) as the PV materials. Moreover, for each PV material commonly deployed in industry today, there is a corresponding range of layer thicknesses and refractive indices wherein a two-layer design will outperform a single layer design, particularly in the presence of a low-index, macroscopically thick transparent superstrate (e.g., 3 mm glass) —the exact thickness will not affect the designs. Using crystalline silicon (c-Si) requires the thickness of the dielectric layer 14 to be in the range between 40 nm and 84 nm having indices between 1.74 and 2.42 and the dielectric layer 12 having thicknesses between 17 nm and 51 nm and indices between 2.83 and 3.92. Using amorphous silicon (a-Si) requires the thickness of the dielectric layer 14 to be in the range between 51 nm and 80 nm having indices between 1.81 and 2.26 and the dielectric layer 12 having thicknesses between 23 nm and 37 nm and indices between 3.18 and 3.85. Using cadmium telluride (CdTe) requires the thickness of the dielectric layer 14 to be in the range between 51 nm and 80 nm having indices between 1.90 and 2.32 and the dielectric layer 12 having thicknesses between 79 nm and 137 nm and indices between 2.58 and 3.41. Finally, using copper indium gallium diselenide (CIGS) requires the thickness of the dielectric layer 14 to be no more than 397 nm having indices between 1.60 and 2.21 and the dielectric layer 12 having thickness no more than 400 nm and indices between 2.15 and 2.99.

The key factor that enables the use of global optimization to exhaustively search the parameter space of possible front-coating films is the availability of extremely efficient algorithms to model the optical properties of multilayer films. In particular, the light-trapping properties of the structures discussed in this paper are studied using a transfer-matrix approach known as the S-matrix method. The structure is broken up into homogeneous slabs of chosen thicknesses, boundary conditions are imposed at the interfaces, and fields are propagated throughout the structure.

The boundary conditions employed correspond to light normally incident from above the solar cell. Light absorption is calculated by modeling the c-Si regions with a complex refractive index that depends on wavelength. The c-Si region is treated as if it is only intrinsic, i.e., the doping of the p- and n-doped regions can be considered to have a negligible impact on the optical properties of the device. Since most dielectric materials have very large band gaps, the dispersion and absorption of the front- and back-coatings is assumed to be negligible over the range of wavelengths considered.

The metal region (back-reflector) is modeled as a frequency independent, negative permittivity (lossless) medium, as shown later, the exact details of the back-reflector have almost no impact on the optimal front coating design for the full solar bandwidth problem. In principle, the calculation of the model's optical properties is exact apart from these approximations. Verification has been performed for several structures using the finite-difference time-domain method with perfectly-matched boundary layers. The results are in good agreement, but the FDTD method is much slower for the same level of accuracy, so it is not used for most calculations.

In order to calculate the efficiency of the light capture of the model one can assume that each absorbed photon with energy greater than the band gap energy generates an electron-hole pair, and both carriers reach the electrical contacts. This corresponds to the statement that the diffusion length L_{D} is much greater than the distance traveled by each carrier (i.e., L_{D}>>d), a reasonable assumption for thin Si films with high mobilities.

The optimized quantity is the generated short-circuit current J_{SC}, given by:

$${J}_{sc} = \int d λ [ \frac{e λ}{hc} \frac{d I}{d λ} A ( λ ) ] ≡ \int d λ w ( λ ) A ( λ ) \qquad ( 1 )$$

where [symbol] represents the light intensity experienced by the solar cell per unit wavelength (given by the ASTM AM1.5 solar spectrum), and A(λ) is the absorption calculated above. (The integration was carried out by a 1000-point trapezoidal rule.) The coefficients w(λ) capture the relative importance of absorption at each wavelength, and will be referred to as “current weights” for short. This allows us to define a figure of merit (FOM) by:

$$FOM = \frac{\int d λ w ( λ ) A ( λ )}{\int d λ w ( λ )} \qquad ( 2 )$$

which is proportional to the objective function used to maximize. It gives us a measure of the absorbing efficiency of the structure weighted for the solar-cell application; perfect absorption at all wavelengths within the range of silicon's absorption (300 nm to 1108 nm) yields FOM=1.

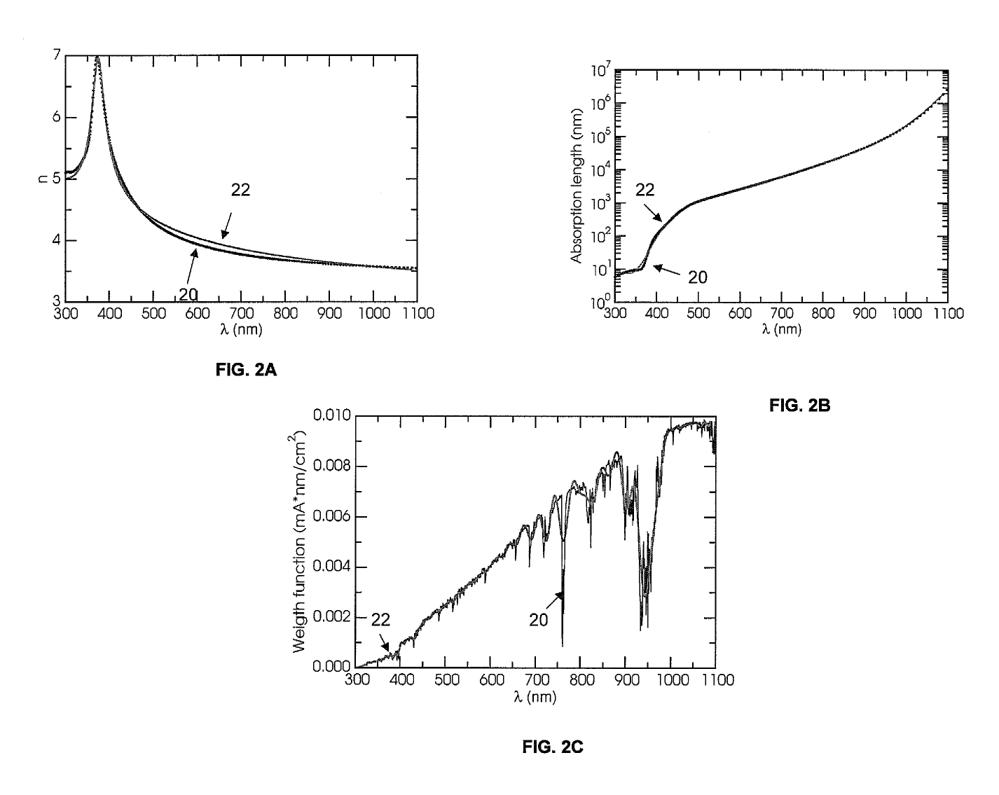

Important spectra factoring into the J_{SC} calculation are displayed in FIGS. 2A-2C: the real indices and absorption lengths of silicon, and current weights w(λ). In each plot, the experimental data is shown in elements 20, while the smooth fit used to calculate the results in the following section is shown in elements 22. For the case of the real index of silicon, a Lorentzian plus a polynomial fits the data well. Since the absorption length grows exponentially with wavelength, a polynomial fit was made to the logarithm of the imaginary part of the index. Finally, the current weighting function w(λ) in Eq. (1), which is based on the AM1.5 solar spectrum, was fit with a degree-100 Chebyshev approximation, which displays more stability than its standard polynomial counterpart.

For the calculations, the front coating thicknesses were bounded by 0 and 700 nm and the indices by 1 and 5. The range of thicknesses includes the largest quarter-wave thickness in the lowest index material; the range of indices includes most materials that can be easily fabricated as a front coating. However, restricting the range of indices to a narrower range, or even fixing the indices entirely to the values for selected materials and optimizing only over the thicknesses, yields a FOM only slightly worse than when a wide range of indices is explored.

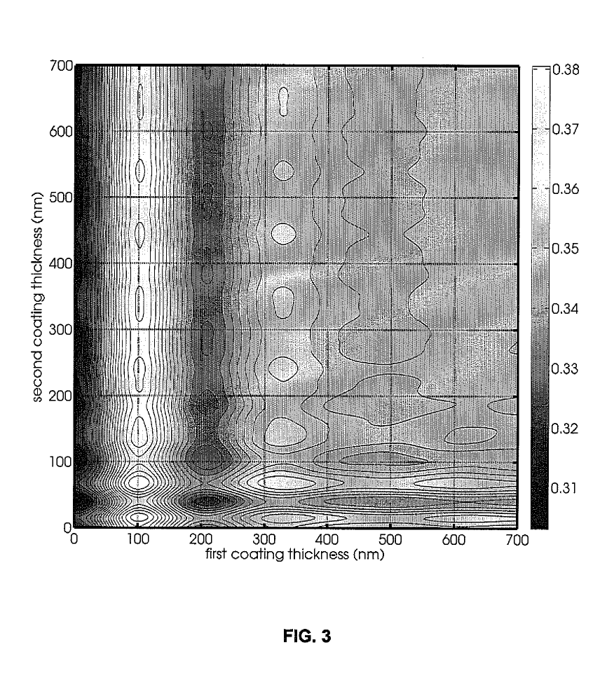

In general, this problem may have many local optima, especially as the range and number of parameters is increased. This is illustrated in FIG. 3, which plots the FOM as a function of two of the four parameters (two coating thicknesses) and exhibits many local optima. To avoid these suboptimal solutions, one can apply a global optimization technique that exhaustively finds all local optima and picks the best one. In particular, one may employ the MLSL algorithm, which combines efficient local search (the limited-memory BFGS algorithm with an open-source implementation is used) with quasi-random starting points based on a Sobol low-discrepancy sequence.

The MLSL algorithm is distinguished by clustering techniques to avoid repeatedly searching the same local optimum, and is guaranteed to find all local optima in a finite number of local searches. Also, the MLSL is compared to several other global-optimization techniques, such as the DIRECT-L algorithm, via a free-software package implementing many optimization algorithms, and found MLSL to find the same optimum in a shorter time. Because the BFGS algorithm requires the gradient of the objective function (the FOM), a computationally efficient method for calculating the gradient based on the adjoint method was used. Adjoint methods allow the gradient to be computed in a time comparable to the time required in calculating the objective function and independent of the number of parameters (here, the front coating indices and thicknesses).

In order to understand the physically-relevant problem of maximizing short-circuit current in a solar cell subject to the AM1.5 solar spectrum, it is instructive to start at the simpler, opposite limit of zero bandwidth. In this zero-bandwidth limit, it is well known that 100% absorption can be achieved when the rate of radiative escape from a resonant cavity is equal to its rate of absorption; this is referred to as the Q-matching condition.

It is predicted that the optimal design of FIGS. 1B-1C with an arbitrary number of front layers should be capable of reaching 100% absorption at any given wavelength, simply by employing a periodic Bragg-mirror structure to confine the light at that wavelength with the appropriate lifetime. For a bounded number of layers, on the other hand, 100% absorption should only be reached up to a certain wavelength λₗ, since for λ>Aₗ the absorption will be too small (corresponding to a high Q that cannot be matched by a small number of layers). The absorption and radiative Q must be large (the absorption length must be much larger than the silicon thickness, and the light must be trapped for a time much larger than the period) in order for it to be accurately described by a resonance process.

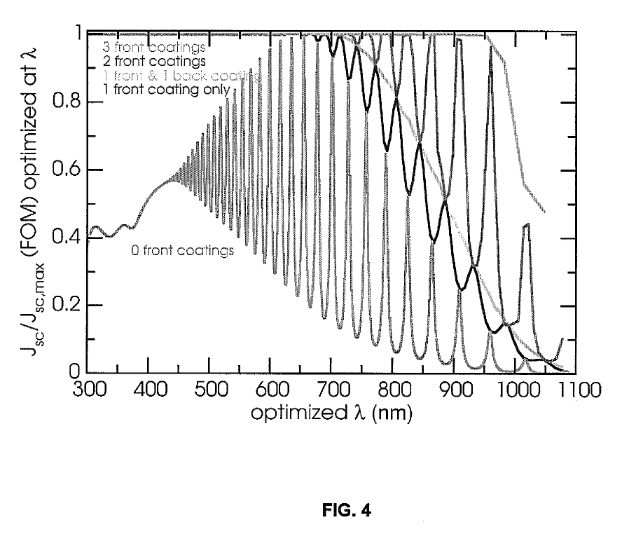

This prediction is tested numerically using the simulation framework discussed in the previous section; the results are shown in FIG. 4. For zero front coating layers, the large dielectric contrast between silicon and air allows effective transmission at only a handful of wavelengths (due to Fabry-Perot oscillations). For a single front coating, the absorption is given by A=1−|r|², where:

$$r = - \frac{{e}^{\text{?}} ( {e}^{\text{?}} + {r}_{0} {r}_{1} ) + {r}_{1} {e}^{\text{?}} + {r}_{0}}{{e}^{\text{?}} ( {r}_{0} {e}^{\text{?}} + {r}_{1} ) + {r}_{0} {r}_{1} {e}^{\text{?}} + 1} \\ \text{?} \text{indicates text missing or illegible when filed} \qquad ( 3 )$$

where layer −1 is air, layer 0 is the front coating, and layer 1 is the silicon; nⱼ is the real part of the refractive index of layer j, κⱼ is the imaginary part, tⱼ is the thickness, λ the vacuum wavelength. At normal incidence, φⱼ=4π(nⱼ+iκⱼ)tⱼ/λ and rⱼ=(nⱼ+iκⱼ−nⱼ₋₁−iκⱼ₋₁)/(nⱼ+iκⱼ+nⱼ₋₁+iκⱼ₋₁) are the phases and Fresnel reflection coefficients.

The reflectance can be divided into three regimes, depending on the fractional absorptance of the silicon layer: The case where |eⁱφ₁|<<r₁: virtually no light reaches the back reflector. Thus, the problem reduces to that of creating an anti-reflection coating between two semi-infinite regions. The reflection is now written as r≈−(r₁eⁱφ₀+r₀)/(r₀r₁eⁱφ₀+1). With the proper choice of front-coating layer index and thickness, 100% transmission (and thus, 100% absorption), can be achieved at a single λ. This is exhibited by the results up to a wavelength of 675 nm in FIG. 4.

The case where |eⁱφ₁|≈r₁: partial absorption after one pass through the cell means that interference between reflections from the front and back surfaces is possible. Furthermore, it is impossible to fully optimize this system by controlling a single, uniform dielectric layer. Mathematically, solving for the root of the numerator of Eq. (3) requires three independent variables because it has four linearly independent terms. If only two independent variables are present, a constant value is added to a term which rotates in the complex plane. This results in Fabry-Perot-type oscillations, which are seen in FIG. 4 for wavelengths ranging from 675 to 1050 nm.

However, these Fabry-Perot oscillations can be suppressed with an additional single back layer, illustrated in FIG. 1C, which shifts the Fabry-Perot oscillations of the silicon slab to a maximum at each λ. To enhance light-trapping at wavelengths where the absorption length of silicon is large, the optimal index of the front coating is the maximum allowed value. Because of the π-phase shift from this layer, the Fabry-Perot peaks are shifted by half a period with respect to the zero front-coating FOM. This trend continues with the two front-coating FOM, there are two π-phase shifts realigning the peaks with the zero front-coating FOM. Finally, note that the onset of these oscillations is red-shifted as the number of front coatings increases, from 675 nm for one front layer, up to 725 nm for two front layers, and 950 nm for three front coatings due to improved light-trapping with an increase in the number of front coatings, as predicted above.

The case where |eⁱφ₁|→1: the absorption strength is virtually nil, and Q-matching cannot be achieved without a number of front layers proportional to log(1−|eⁱφᵢ|), since the maximum reflectivity goes exponentially with the number of layers. Mathematically, the amplitude of the reflection coefficient |r| will approach unity. This limit is approached on the right-hand side of FIG. 4.

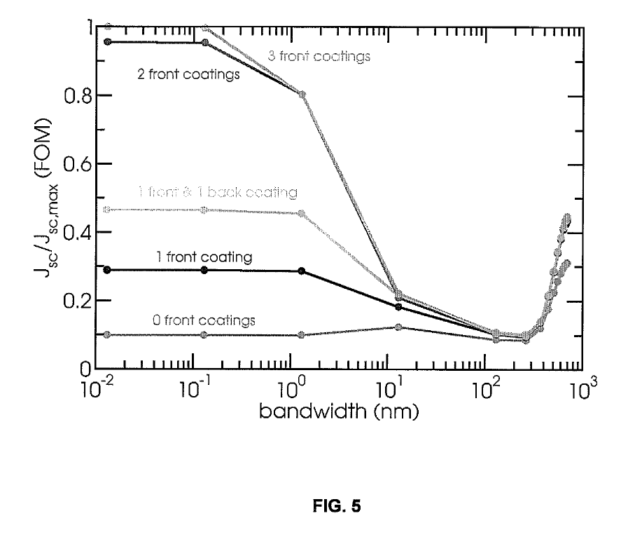

Next, consider what happens to the FOM as the window of absorption wavelengths expands from zero up to the width of the usable solar spectrum for silicon-based solar cells (300-1108 nm). The results for optimized structures with 0-3 front layers are plotted in FIG. 5; three distinct bandwidth regimes can be seen. First, the smallest bandwidths (below 1 nm) are similar to the zero bandwidth problem plotted in FIG. 5, for λ=902.8 nm. Since the absorption length of silicon at λ=902.8 nm is about 50 μm, several front layers are necessary to increase the radiative Q for Q-matching to be achieved. Second, it is evident that Q-matching starts to break down for bandwidths greater than 1 nm. That is because Q-matching relies on the accuracy of coupled-mode theory, which assumes a narrow-bandwidth cavity (i.e., one that is weakly coupled to losses so that its decay rate is long compared to the optical period. When that assumption is violated, it is no longer possible to achieve 100% absorption over the entire bandwidth; the severity of the violation dictates the extent of the decrease in the average absorption. Third, the increase in the FOM for large bandwidths (above 265 nm) demonstrate that absorption can be boosted by blue-shifting the central wavelength and adding in more wavelengths for which even a thin film is optically thick.

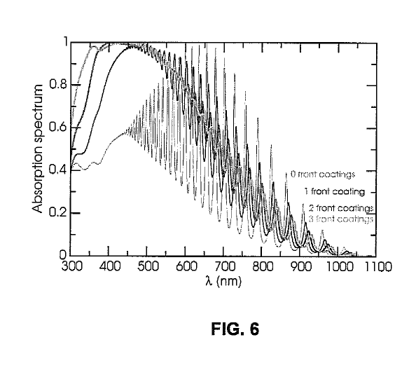

Now let us consider the problem of absorption over the whole solar spectrum in more detail. The absorption spectra of optimized thin-film crystalline silicon solar cells (t=2 μm) are plotted in FIG. 6 for structures with no front layers, based on FIG. 1A, as well as optimized structures with 1-3 front layers, based on FIG. 1B. It is evident that the optimal design employs a peak absorption around 450 nm, which represents a trade off between the shorter absorption lengths at smaller wavelengths, as illustrated in FIG. 2A, and the greater current weights at longer wavelengths, as illustrated in FIG. 2B.

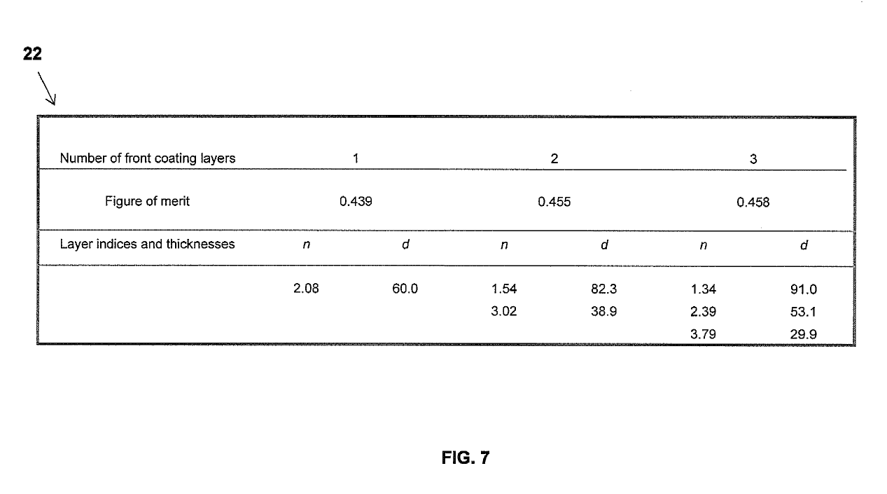

The values of the front coating indices, thicknesses and figure of merit for the optimized structures of FIG. 6 are listed in Table 22, shown in FIG. 7. The layers slowly increase in index towards the silicon layer, consistent with the intuition that a front layer with a smoothly increasing index profile would allow 100% transmission to the silicon layer. The optimal front coating is not a total transmission AR coating, however, because it must act as a partially silvered mirror, particularly in the narrow-bandwidth limit.

Moreover, as one might expect, each of the optimized front coatings generates destructive interference between reflections from their front and back at the central frequency (corresponding to a phase shift≈π). In addition, the optimized structure for the 1 front-coating and 1 back-coating structure was found to be d=60.0 nm, n=2.070 and d=20.7 nm, n=1, respectively; the corresponding figure of merit was 0.440, which is nearly the same as the 1 front-layer structure. While it appears that the back layer is not much use in a broad bandwidth problem, for a lossy metal backing the back layer can help to reduce unwanted absorption loss.

Let us consider the effects of thickness over a broad range of silicon thicknesses, from thin-film values of 1 μm to effectively semi-infinite values of 1.6 cm. For the case of 2 μm-thick thin films, increasing the number of front coatings from zero to one yields a relative increase of 39.8% to the FOM (from 0.314 to 0.439); adding a second front coating yields a relative increase of 3.6% to the FOM (to 0.455), and adding a third coating yields another relative increase of 0.6% (to 0.458). For wafer-based cell thicknesses, e.g., 256 μm, increasing the number of front coatings from zero to one yields a 42.3% relative increase in the FOM (from 0.614 to 0.874); adding a second coating yields a relative increase of 6.1% (to 0.927); adding a third coating yields a relative increase of 1.3%. For effectively semi-infinite cells, e.g., 1.6 cm, increasing the number of front coatings from zero to one yields a 42.0% relative increase to the FOM (from 0.645 to 0.916); adding a second coating yields a 6.6% relative increase (to 0.976); and adding a third coating yields a relative increase of 1.5% (to 0.991).

These numbers illustrate the diminishing returns associated with adding more front layers for the broad-bandwidth problem. Thus, it comes as no surprise that increasing the number of layers to 10 provides no more than a 0.5% relative improvement over 3 layers, for a 2 μm-thick thin film. This result contrasts strongly with the zero-bandwidth results shown in FIG. 4, where each additional layer results in a large improvement (up to the critical number required for Q-matching). As discussed previously, this crossover occurs in the intermediate bandwidth regime (1-265 nm), as illustrated in FIG. 5.

Furthermore, it is intriguing to note that both the relative and absolute gains are greater for the thicker, wafer-based cells than for thin films. This can be explained by noting that the long wavelengths that are poorly absorbed by thin cells with a single front coating layer can be absorbed well by thick cells. Thin-film cells are simply too thin to ever strongly absorb longer wavelengths without compromising their shorter-wavelength absorption, whereas wafer-based cells are free from this limitation. This assertion is also supported by the absorption spectra of FIG. 6, in which the optimal designs display increasing absorption with the number of front coatings primarily at shorter wavelengths. However, this picture can change in the presence of enhanced light-trapping schemes in thin-film cells. Such light-trapping schemes will broaden the effective bandwidth absorbed, leading to a larger benefit from 2 or more front coating layers.

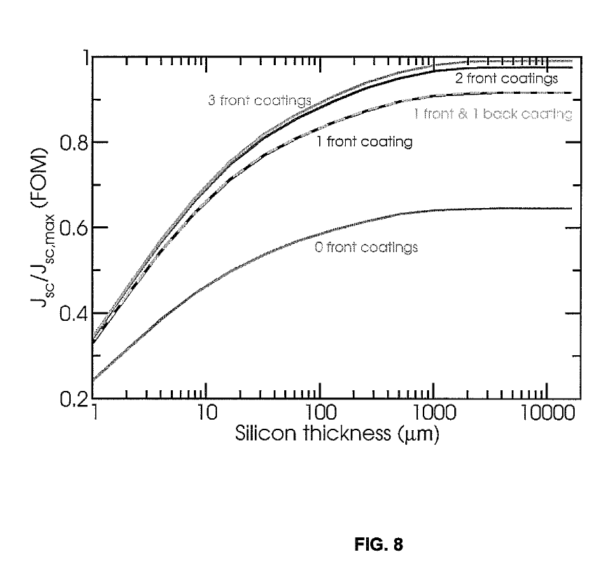

FIG. 8 shows the figure of merit (FOM) versus silicon slab thickness, both for a structure with no front layer (based on FIG. 1A) and optimized structures with 1-3 front layers (based on FIG. 1B).

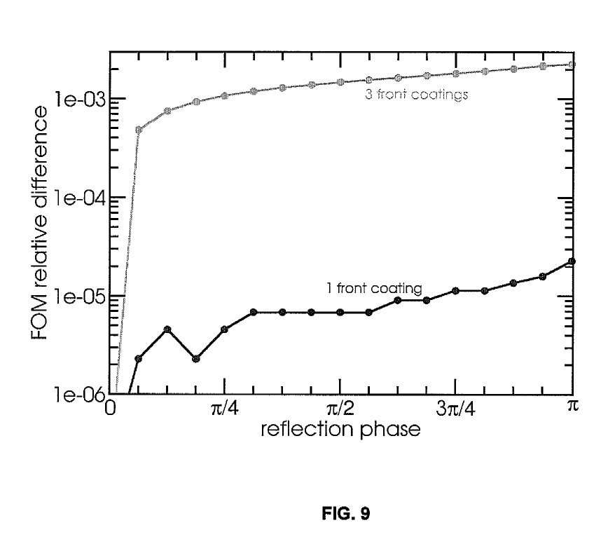

For thin films exposed to the full solar bandwidth, the FOM and the optimal front-coating design are insensitive to the type of back-reflector. Considering only lossless planar back-reflectors, limiting to 100% specular reflection, different back-reflector schemes (different materials, Bragg mirrors, etc.) are distinguished only by the phase θ of the reflected wave. However, one can show here that the FOM is essentially independent of the back-reflector phase. Of course, the phase generally varies with wavelength, but it is sufficient to demonstrate this independence using a constant phase (employing n=3.5 for silicon and a constant imaginary index for the back-reflector, as explained previously). The FOM relative difference, which measures the influence of the back-reflector on the absorption, versus θ is shown in FIG. 9. For each back reflector, the FOM must be calculated twice, once with the optimal front coating design for that particular back reflector and again with the optimal front coating design of the original back reflector (θ=0). One can find the relative difference to be very small, less than 0.0001 for the single front-coating structure.

This robust behavior is enabled by the large bandwidth of the incident flux that averages out the change at each λ; while the location of the absorption peaks can shift, the total absorbed flux will show almost no change as illustrated in FIG. 9. Therefore, metallic backings where absorptive losses are present, such as aluminum, can be replaced with a lossless backing, such as a 1D Bragg mirror.

Though the refractive index bounds exceed those of common materials, one can find that optimization with a smaller range of indices, 1 to 3, does not significantly change the FOM. In fact with a restricted refractive index range, the 3 front-coating structure FOM decreases by less than 0.5% (0.458 to 0.456). (The thicknesses and indices of each layer of the optimal structure changes, even those in the original structure with an index less than 3.) Moreover, if the indices of the front coatings were fixed to values corresponding to experimentally accessible materials and allow only the thicknesses to vary, one can find the FOM changes very little, less than a 0.2% relative change in all three cases. If the front coatings were chosen to be MgF₂, ZrO₂, and TiO₂ with indices 1.38, 2.39, and 3.9 yields a FOM of 0.457, a relative decrease of just 0.2% compared to the optimal 3 front-coating structure in Table 22 of FIG. 7.

The designs presented in this work are also robust against small fabrication errors. For example, vertical LPCVD systems can routinely achieve uniformities of better than 2% in the deposition of silicon nitride. For the designs, that corresponds to an error of ±2 nm or less. However, it's clear that this corresponds to a variation in the objective function of less than 0.001, which shows that the designs can tolerate typical experimental errors.

The proper design and optimization of front coatings of crystalline silicon solar cells has a critical impact on their overall efficiency. For narrow bandwidths in optically thin absorbing media, it is best to employ the Q-matching condition. The benefit of additional layers is large until this criterion is achieved. When the bandwidth is equal to the portion of the solar spectrum that can be absorbed by crystalline silicon, it is necessary to take a different approach. It is found that just two optimized layers (going from low to high index) suffice to realize most of the benefits of a multilayer front coating design. The relative improvement associated with going from one to two front layers is 6.1% for 256 micron-thick wafer-based cells, and only 3.6% for 2 micron-thick thin-film cells. This result comes about because weak absorption of near-IR by planar thin films limits the utility of broadening the bandwidth of strong transmission through the front coating. Adding a third layer yields relative improvements of 1.3% and 0.6% for wafers and thin films, respectively; the results for four or more layers show even smaller additional improvements. Finally the broad bandwidth results achieved do not depend on the type of back-reflector used.

Furthermore, the weak absorption of near-IR by thin-film cells can be improved by introducing optimized 2D or 3D patterns in the front or back coatings, whose purpose is to convert incoming normal incidence radiation to transversely propagating, waveguided modes that achieve a longer optical path within the absorbing layer. It has been demonstrated how photonic crystals can improve reflection off of a realistic, lossy metal (such as aluminum) while also redirecting light in the near-IR into guided modes. They should also enable front coatings to improve absorption over a broader wavelength range than would be possible in a planar structure. This combined approach may result in efficiency gains equal to the sum of their contributions. The method presented in this patent can also be extended to include the effect of non-normally incident radiation, so as to maximize the performance over a range of incident angles. The results outlined in this work also provide a clear baseline to which more complex, non-planar photonic structures ought to be compared.

Although the present invention has been shown and described with respect to several preferred embodiments thereof, various changes, omissions and additions to the form and detail thereof, may be made therein, without departing from the spirit and scope of the invention.

What is claimed is:

1. A solar cell comprising:
a photovoltaic material structure used in absorbing light of a selective bandwidth, said photovoltaic material structure having a thickness of 50 μm or less; and
a plurality of dielectric front coatings positioned on said photovoltaic material structure so as to maximize admittance over said selected bandwidth, the thicknesses and indices of each of said front coatings are chosen by a global-optimization procedure to maximize the short-circuit current of said solar cell.

2. The solar cell of claim 1 further comprising a reflective metal layer to maximize reflections in said photovoltaic material structure.

3. The solar cell of claim 2 further comprising a dielectric back coating positioned between said photovoltaic materials structure and said reflective metal layer.

4. The solar cell of claim 1, wherein said dielectric front coatings comprise two dielectric layers.

5. The solar cell of claim 3, wherein said dielectric back coating comprises a low-loss planar layer.

6. The solar cell of claim 4, wherein said photovoltaic material structure comprises crystalline silicon (c-Si), the first said dielectric front coating comprises thicknesses between 40 and 84 nm and indices between 1.74 and 2.42, and the second said dielectric front coating comprises thicknesses between 17 and 51 nm and indices between 2.83 and 3.92.

7. The solar cell of claim 4, wherein said photovoltaic material structure comprises cadmium telluride (CdTe), the first said dielectric front coating comprises thicknesses between 51 and 80 nm and indices between 1.90 and 2.32, and the second said dielectric front coating comprises thicknesses between 79 and 137 nm and indices between 2.58 and 3.41.

8. The solar cell of claim 4, wherein said photovoltaic material structure comprises copper gallium indium diselenide (CIGS), the first said dielectric front coating comprises thicknesses no more than 397 nm and indices between 1.60 and 2.21, and the second said dielectric front coating comprises thicknesses no more than 400 nm and indices between 2.15 and 2.99.

9. The solar cell of claim 4, wherein said photovoltaic material structure comprises amorphous silicon (a-Si), the first said dielectric front coating comprises thicknesses between 51 and 80 nm and indices between 1.81 and 2.26, and the second said dielectric front coating comprises thicknesses between 23 and 37 nm and indices between 3.18 and 3.85.

10. A method of forming a solar cell comprising:
providing a photovoltaic material structure used in absorbing light of a selective bandwidth, said photovoltaic material structure having a thickness of 50 μm or less; and
positioning a plurality of dielectric front coatings on said thin film photovoltaic material structure so as to maximize admittance over said selected bandwidth, the thicknesses and indices of each of said front coatings are chosen by a global-optimization procedure to maximize the short-circuit current of said solar cell.

11. The method of claim 11 further comprising positioning a reflective metal layer to maximize reflections in said photovoltaic material structure.

12. The method of claim 12 further comprising positioning a dielectric back coating between said photovoltaic material structure and said reflective metal layer.

13. The method of claim 1, wherein said dielectric front coatings comprise two dielectric layers.

14. The method of claim 11, wherein said dielectric back coating comprises a low-loss planar layer.

15. The method of claim 13, wherein said photovoltaic material structure comprises crystalline silicon (c-Si), the first said dielectric front coating comprises thicknesses between 40 and 84 nm and indices between 1.74 and 2.42, and the second said dielectric front coating comprises thicknesses between 17 and 51 nm and indices between 2.83 and 3.92.

16. The method of claim 13, wherein said photovoltaic material structure comprises cadmium telluride (CdTe), the first said dielectric front coating comprises thicknesses between 51 and 80 nm and indices between 1.90 and 2.32, and the second said dielectric front coating comprises thicknesses between 79 and 137 nm and indices between 2.58 and 3.41.

17. The method of claim 13, wherein said photovoltaic material structure comprises copper gallium indium diselenide (CIGS), the first said dielectric front coating comprises thicknesses up to 397 nm and indices between 1.60 and 2.21, and the second said dielectric front coating comprises thicknesses up to 400 nm and indices between 2.15 and 2.99.

18. The method of claim 13, wherein said photovoltaic material structure comprises amorphous silicon (a-Si), the first said dielectric front coating comprises thicknesses between 51 and 80 nm and indices between 1.81 and 2.26, and the second said dielectric front coating comprises thicknesses between 23 and 37 nm and indices between 3.18 and 3.85.
